(19) United States
(12) Patent Application Publication
(10) Pub. No.: US 2015/0279847 A1
(43) Pub. Date: Oct. 1, 2015

(54) SEMICONDUCTOR MEMORY DEVICE AND METHOD OF MANUFACTURING THE SAME

(71) Applicant: KABUSHIKI KAISHA TOSHIBA, Tokyo (JP)

(72) Inventor: Masayoshi TAGAMI, Kuwana Mie (JP)

(21) Appl. No.: 14/475,563

(22) Filed: Sep. 2, 2014

(30) Foreign Application Priority Data
Mar. 31, 2014 (JP) 2014-074502

(51) Int. Cl. H01L 27/112

(52) U.S. Cl. CPC H01L 27/11286

(57) ABSTRACT

A semiconductor memory device includes a semiconductor substrate that includes an active region and an element isolation region which are alternately arranged in a first direction and extend in a second direction orthogonal to the first direction, a first contact portion that is electrically connected to the semiconductor substrate, and has a width in the first direction which continuously narrows in a third direction perpendicular to the semiconductor substrate, and a width in the second direction which continuously widens in the third direction, and a metal wiring line extending in the second direction, that is provided on an upper portion of the first contact portion, and has a width in the first direction at a surface thereof in contact with the first contact portion which is as large as a width of the upper portion of the first contact portion and which continuously narrows in the third direction.

### CROSS-REFERENCE TO RELATED APPLICATION

This application is based upon and claims the benefit of priority from Japanese Patent Application No. 2014-074502, filed Mar. 31, 2014, the entire contents of which are incorporated herein by reference.

### FIELD

Embodiments described herein relate generally to a semiconductor memory device and a method of manufacturing the same.

### BACKGROUND

In recent years, the area of memory cells has been reduced due to the demand for denser packing of memory cells. The memory cells are provided at a position where bit lines cross a plurality of word lines in a direction orthogonal to the bit lines. The bit line is configured as a plurality of metal wiring lines, and bit line contacts extend in a vertical direction to an active region of a substrate. The metal wiring lines are positioned, and formed, over and contacting a top surface of the contacts. Accordingly, when the spacing or distance between the adjacent metal wiring lines is reduced with the reduced area of the memory cell, the metal wiring lines may not be positioned over the contacts with a sufficiently high level of accuracy, and there is a resulting risk that the metal wiring lines may come into contact with an adjacent contact, and that the adjacent metal wiring lines may be sufficiently close to allow leakage current to flow therebetween.

### DESCRIPTION OF THE DRAWINGS

FIG. 1 is a partial schematic plan view illustrating a configuration of a semiconductor memory device.

FIG. 2 is a partial schematic cross-sectional view taken along line Iₐ-Iₐ of the semiconductor memory device illustrated in FIG. 1.

FIG. 3 is a partial schematic cross-sectional view taken along line I_{b}-I_{b} of the semiconductor memory device illustrated in FIG. 1.

FIGS. 4A to 4C are diagrams illustrating a method of manufacturing a semiconductor memory device according to a first embodiment; FIG. 4A is a cross-sectional view taken along line Iₐ-Iₐ of the semiconductor memory device illustrated in FIG. 1, FIG. 4B is a cross-sectional view taken along line I_{b}-I_{b} of the semiconductor memory device illustrated in FIG. 1, and FIG. 4C is an enlarged plan view of a region I_{c} of the semiconductor memory device illustrated in FIG. 1.

FIGS. 5A to 5C are diagrams illustrating a method of manufacturing a semiconductor memory device according to the first embodiment; FIG. 5A is a cross-sectional view taken along line Iₐ-Iₐ of the semiconductor memory device illustrated in FIG. 1, FIG. 5B is a cross-sectional view taken along line I_{b}-I_{b} of the semiconductor memory device illustrated in FIG. 1, and FIG. 5C is an enlarged plan view of the region I_{c} of the semiconductor memory device illustrated in FIG. 1.

FIGS. 6A to 6C are diagrams illustrating a method of manufacturing a semiconductor memory device according to the first embodiment; FIG. 6A is a cross-sectional view taken along line Iₐ-Iₐ of the semiconductor memory device illustrated in FIG. 1, FIG. 6B is a cross-sectional view taken along line I_{b}-I_{b} of the semiconductor memory device illustrated in FIG. 1, and FIG. 6C is an enlarged plan view of the region I_{c} of the semiconductor memory device illustrated in FIG. 1.

FIGS. 7A to 7C are diagrams illustrating a method of manufacturing a semiconductor memory device according to the first embodiment; FIG. 7A is a cross-sectional view taken along line Iₐ-Iₐ of the semiconductor memory device illustrated in FIG. 1, FIG. 7B is a cross-sectional view taken along line I_{b}-I_{b} of the semiconductor memory device illustrated in FIG. 1, and FIG. 7C is an enlarged plan view of the region I_{c} of the semiconductor memory device illustrated in FIG. 1.

FIGS. 8A to 8C are diagrams illustrating a method of manufacturing a semiconductor memory device according to the first embodiment; FIG. 8A is a cross-sectional view taken along line Iₐ-Iₐ of the semiconductor memory device illustrated in FIG. 1, FIG. 8B is a cross-sectional view taken along line I_{b}-I_{b} of the semiconductor memory device illustrated in FIG. 1, and FIG. 8C is an enlarged plan view of the region I_{c} of the semiconductor memory device illustrated in FIG. 1.

FIGS. 9A to 9C are partial schematic cross-sectional views of the semiconductor memory device according to the first embodiment; FIG. 9A is a cross-sectional view taken along line Iₐ-Iₐ of the semiconductor memory device illustrated in FIG. 1, FIG. 9B is a cross-sectional view taken along line I_{b}-I_{b} of the semiconductor memory device illustrated in FIG. 1, and FIG. 9C is an enlarged plan view of the region I_{c} of the semiconductor memory device illustrated in FIG. 1.

FIGS. 10A to 10C are partial schematic cross-sectional views of the semiconductor memory device according to the first embodiment; FIG. 10A is a cross-sectional view taken along line Iₐ-Iₐ of the semiconductor memory device illustrated in FIG. 1, FIG. 10B is a cross-sectional view taken along line I_{b}-I_{b} of the semiconductor memory device illustrated in FIG. 1, and FIG. 10C is an enlarged plan view of the region I_{c} of the semiconductor memory device illustrated in FIG. 1.

FIGS. 11A to 11C are partial schematic cross-sectional views of the semiconductor memory device according to the first embodiment; FIG. 11A is a cross-sectional view taken along line Iₐ-Iₐ of the semiconductor memory device illustrated in FIG. 1, FIG. 11B is a cross-sectional view taken along line I_{b}-I_{b} of the semiconductor memory device illustrated in FIG. 1, and FIG. 11C is an enlarged plan view of the region I_{c} of the semiconductor memory device illustrated in FIG. 1.

FIGS. 12A to 12C are partial schematic cross-sectional views of a semiconductor memory device according to a second embodiment; FIG. 12A is a cross-sectional view taken along line Iₐ-Iₐ of the semiconductor memory device illustrated in FIG. 1, FIG. 12B is a cross-sectional view taken along line I_{b}-I_{b} of the semiconductor memory device illustrated in FIG. 1, and FIG. 12C is an enlarged plan view of the region I_{c} of the semiconductor memory device illustrated in FIG. 1.

FIGS. 13A to 13C are partial schematic cross-sectional views of the semiconductor memory device according to the second embodiment; FIG. 13A is a cross-sectional view taken along line Iₐ-Iₐ of the semiconductor memory device illustrated in FIG. 1, FIG. 13B is a cross-sectional view taken along line I_{b}-I_{b} of the semiconductor memory device illustrated in FIG. 1, and FIG. 13C is an enlarged plan view of the region I_{c} of the semiconductor memory device illustrated in FIG. 1.

FIGS. 14A to 14C are partial schematic cross-sectional views of the semiconductor memory device according to the second embodiment; FIG. 14A is a cross-sectional view taken along line Iₐ-Iₐ of the semiconductor memory device illustrated in FIG. 1, FIG. 14B is a cross-sectional view taken along line I_{b}-I_{b} of the semiconductor memory device illustrated in FIG. 1, and FIG. 14C is an enlarged plan view of the region I_{c} of the semiconductor memory device illustrated in FIG. 1.

FIGS. 15A to 15C are partial schematic cross-sectional views of the semiconductor memory device according to the second embodiment; FIG. 15A is a cross-sectional view taken along line Iₐ-Iₐ of the semiconductor memory device illustrated in FIG. 1, FIG. 15B is a cross-sectional view taken along line I_{b}-I_{b} of the semiconductor memory device illustrated in FIG. 1, and FIG. 15C is an enlarged plan view of the region I_{c} of the semiconductor memory device illustrated in FIG. 1.

FIGS. 16A to 16C are partial schematic cross-sectional views of the semiconductor memory device according to the second embodiment; FIG. 16A is a cross-sectional view taken along line Iₐ-Iₐ of the semiconductor memory device illustrated in FIG. 1, FIG. 16B is a cross-sectional view taken along line I_{b}-I_{b} of the semiconductor memory device illustrated in FIG. 1, and FIG. 16C is an enlarged plan view of the region I_{c} of the semiconductor memory device illustrated in FIG. 1.

FIGS. 17A to 17C are partial schematic cross-sectional views of the semiconductor memory device according to the second embodiment; FIG. 17A is a cross-sectional view taken along line Iₐ-Iₐ of the semiconductor memory device illustrated in FIG. 1, FIG. 17B is a cross-sectional view taken along line I_{b}-I_{b} of the semiconductor memory device illustrated in FIG. 1, and FIG. 17C is an enlarged plan view of the region I_{c} of the semiconductor memory device illustrated in FIG. 1.

### DETAILED DESCRIPTION

Embodiments provide a semiconductor memory device and a method of manufacturing the same which are capable of reducing misalignment between a metal wiring line and a contact.

In general, according to one embodiment, a semiconductor memory device includes a semiconductor substrate that includes an active region and an element isolation region which are alternately arranged in a first direction and extend in a second direction orthogonal to the first direction; a first contact portion that is electrically connected to the semiconductor substrate over an active region, and has a width in the first direction which continuously becomes narrower along a third direction perpendicular to the semiconductor substrate, and a width in the second direction which continuously becomes wider along the third direction; and a metal wiring line that is provided contacting an upper portion of the first contact portion and extends in the second direction, and has a width in the first direction at a surface thereof in contact with the first contact portion which is as large as a width of the upper portion of the first contact portion and which continuously becomes narrower along the third direction.

Hereinafter, exemplary embodiments will be described with reference to the accompanying drawings.

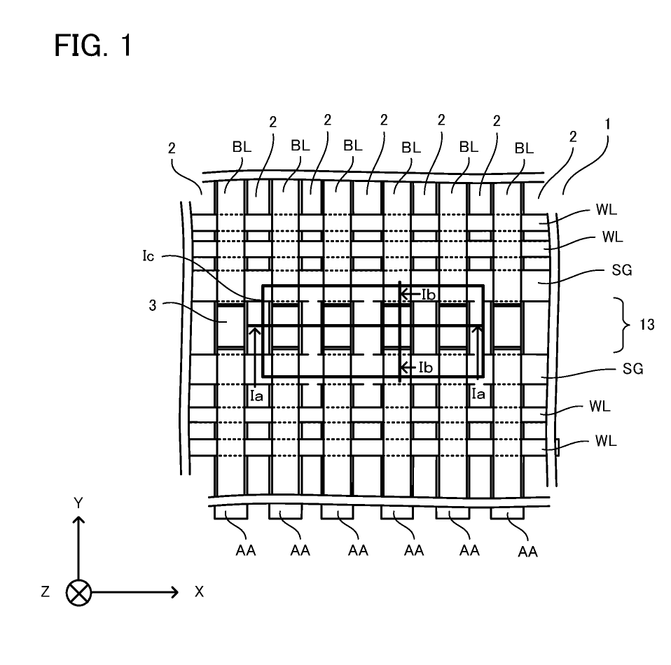

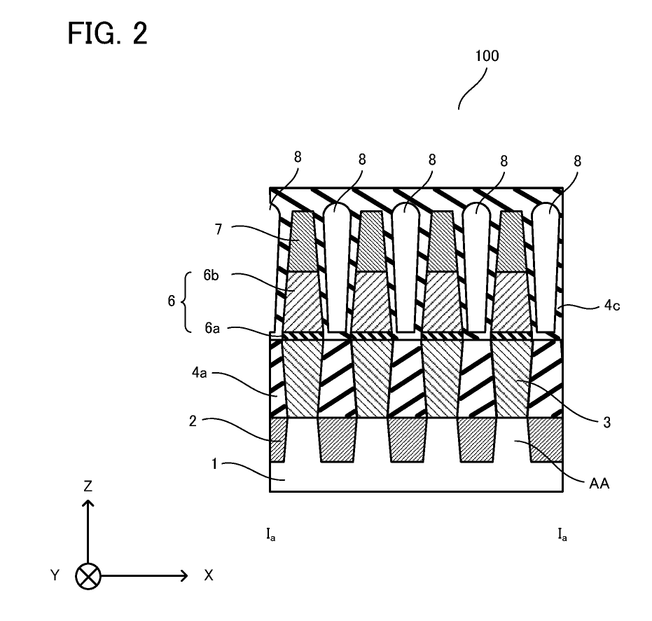

Referring to FIGS. 1 and 2, a semiconductor memory device 100 includes a semiconductor substrate 1, element isolation regions 2, first contacts 3, insulating films 4, second contacts 6, metal wiring lines 7, insulating regions 8, active regions AA, bit lines BL, word lines WL, and selected gate lines SG.

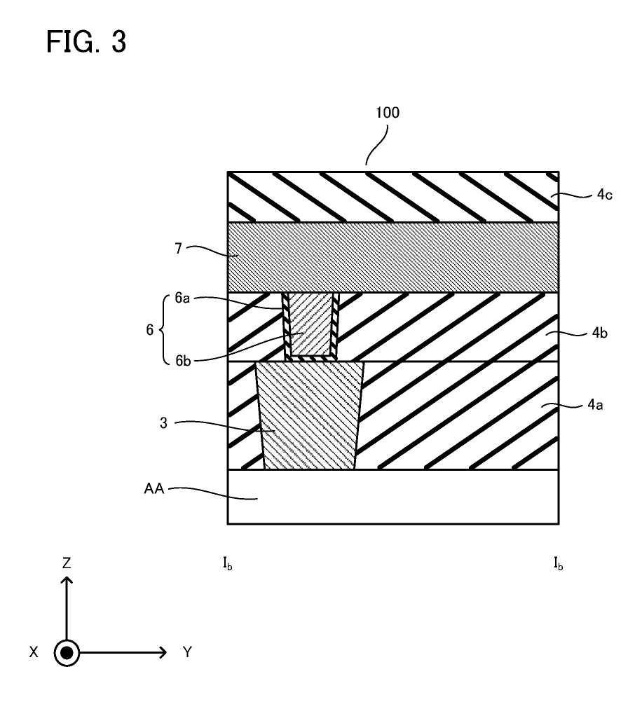

For convenience of description, the insulating film 4 is assumed to be a first insulating film 4a, a second insulating film 4b (FIG. 3), and a third insulating film 4c.

### First Embodiment

A semiconductor memory device according to a first embodiment will be described with reference to FIGS. 1 to 3. FIG. 1 is a schematic diagram illustrating a configuration of the semiconductor memory device 100. FIG. 2 is a cross-sectional view taken along line Iₐ-Iₐ of the semiconductor memory device according to this embodiment. FIG. 3 is a cross-sectional view taken along line I_{b}-I_{b} of the semiconductor memory device according to this embodiment. In the sectional views, structures in the background of a Figure which are not sections are omitted for clarity of understanding of the Figure.

The semiconductor substrate 1 is provided with the plurality of element isolation regions 2 extending in a Y direction of FIG. 1. In this embodiment, among directions parallel to the semiconductor substrate 1, a direction in which the element isolation regions 2 and the active regions AA extend is designated the Y direction and a direction orthogonal to the Y direction is designated the X direction. A direction perpendicular to the semiconductor substrate 1 is designated the Z direction. The plurality of element isolation regions 2 are spaced apart in the X direction so as to be separated from each other by the active regions AA in the substrate 1. The active regions AA are likewise separated from one another and located extending inwardly of the upper-surface of the semiconductor substrate 1, or a layer formed thereon, by the element isolation regions 2 which likewise extend inwardly of the upper-surface of the semiconductor substrate 1.

The bit lines BL are provided above the active regions AA so as to extend in the Y direction and be spaced apart in the X direction and overlie the active regions AA.

The word lines WL extend in the X direction and are spaced in the Y direction at predetermined intervals.

The selector gate lines SG are disposed at both ends of pluralities of the word lines WL.

The first contacts 3 are provided on, and extend in the Z direction from, each of the respective active regions AA in a contact line bit region 13 between the adjacent selector gate lines SG.

As illustrated in FIG. 2, the second contacts 6 are configured to include a barrier metal layer 6a provided on the first contact 3 and a via metal layer 6b located thereover and extending in the Z direction from the barrier metal layer 6a. The barrier metal layer 6a is provided only on the surface of the first contacts 3 between the first contacts 3 and the second contacts 6 and extends in the direction X as illustrated in FIG. 2, and on the lateral sides of the second contacts 6 which would otherwise come into contact with the second insulating film 4b, and on a connection surface between the first contacts 3 and the second contacts 6 in the Y direction as illustrated in FIG. 3. For example, titanium nitride (TiN) is used as a material of the barrier metal layer 6a. For example, a metal material such as tungsten (W) is used as a material of the via metal layer 6b. The width, in the X direction, of the upper portion of the second contact 6 is narrower than the width thereof in the lower portion of the second contact 6 as illustrated in FIG. 2. The width, in the Y direction, of the upper portion of the second contact 6 is wider than that of the lower portion of the second contact 6 in the cross-section thereof illustrated in FIG. 3. The width of the upper portion of the second contacts 6 in the X direction is the same as the width of a contact area or surface of the lower surface of the metal wiring lines 7 (the details of which will be described later herein).

The metal wiring lines 7 are provided over, and directly contacting, the second contacts 6. As illustrated in FIG. 2, the width of the upper portion of the metal wiring lines 7 in the X direction is narrower than that of the lower portion of the metal wiring lines 7. In other words, the metal wiring lines 7 and the second contacts 6 below each of the wiring lines 7 are configured in such a manner that the widths thereof in the X direction continuously become wider from the uppermost portion of the metal wiring lines 7 toward the lowermost portion of the second contact 6. In addition, the lateral sides of the metal wiring lines 7 and the second contacts 6 therebelow (between each metal wiring line 7 and the substrate 1 are co-planar and with no shift or offset therebetween. Hereinafter, co-planar with no shift or offset between the lateral sides of structures will be expressed as being flush with each other. A metal material such as, for example, tungsten is used as a material of the metal wiring lines 7. As illustrated in FIG. 3, each of the metal wiring lines 7 extend in the Y direction.

As illustrated in FIGS. 2 and 3, the third insulating film 4c is provided on the metal wiring lines 7, between the adjacent metal wiring lines 7, and between the adjacent second contacts 6. The third insulating film 4c is formed on the lateral sides of the metal wiring lines 7 and on the lateral sides of the second contacts 6. The third insulating film 4c is a silicon oxide film which is formed by, for example, a CVD method.

The insulating regions 8 extend between adjacent metal wiring lines 7 and between the adjacent second contacts 6 and are surrounded by the third insulating film 4c. An uppermost portion of the insulating region 8 is located on the upper side with respect to the upper portion of the metal wiring 7. The insulating region 8 is, for example, air.

As described above, the wiring line-contact structure according to this embodiment is configured such that the width thereof, in the X direction, continuously widens from the uppermost portion of the metal wiring lines 7 toward the lowermost portion of the second contacts 6 and such that the lateral sides of the metal wiring lines 7 and the second contacts 6 are flush with each other. Accordingly, since a contact area or surface where the metal wiring lines 7 and the second contacts 6 therebelow are joined is consistently the same, and thus maximized under the design rules because no misalignment between the lower surface of a wiring line 7 and upper surface of a contact occurs, it is possible to reduce contact resistance therebetween. Further, since misalignment does not occur between the metal wiring lines 7 and the second contact 6, it is possible to suppress an increase in leakage current between the adjacent metal wiring lines 7 and between the adjacent second contacts 6 which could otherwise occur if a wiring line 7 is offset or improperly “landed” on the intended contact(s) 6, and thus close enough to an adjacent contact 6 and/or wiring line 7 to allow electric charge, and thus electric current, to leak across the insulating material 7 therebetween. Further, since the insulating region 8 having a low dielectric constant is present between the adjacent metal wirings 7 and between the adjacent second contacts 6, it is possible to reduce parasitic capacitance.

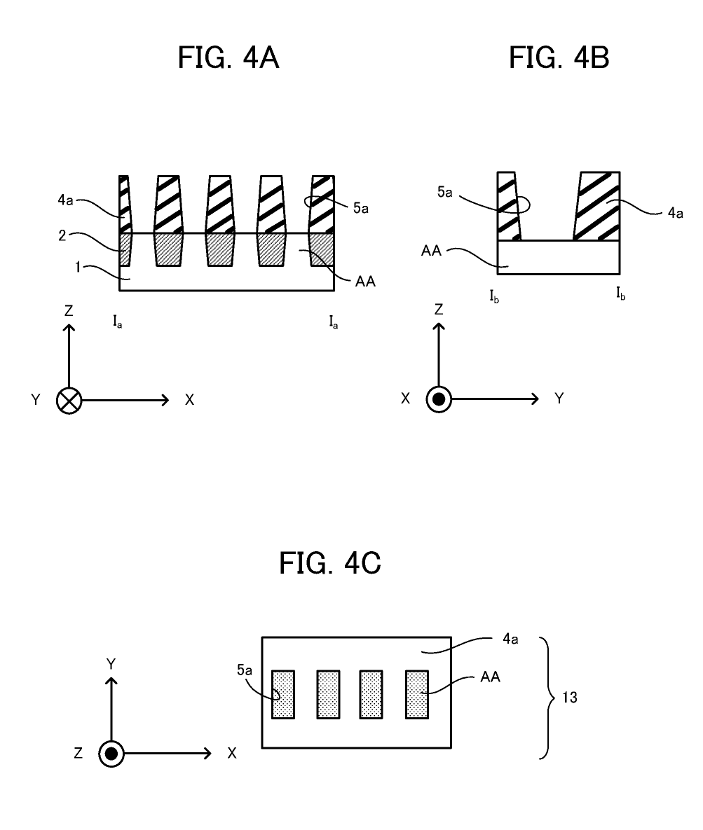

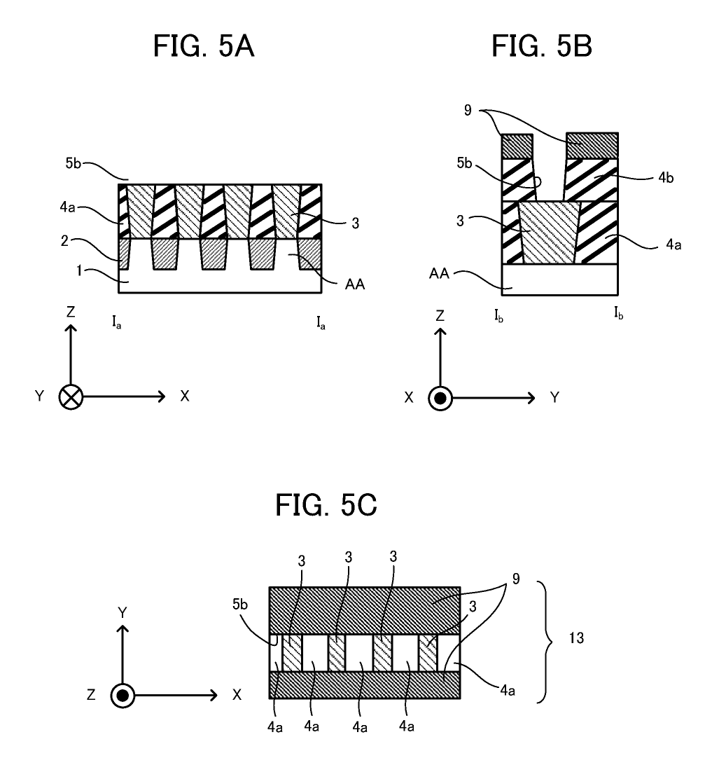

Next, a process of manufacturing the semiconductor memory device according to this embodiment will be described with reference to FIGS. 4A to 11C. FIG. 4A is a cross-sectional view taken along line Iₐ-Iₐ of the semiconductor memory device according to this embodiment illustrated in FIG. 1. FIG. 4B is a cross-sectional view taken along line I_{b}-I_{b} of the semiconductor memory device according to this embodiment illustrated in FIG. 1. FIG. 4C is an enlarged plan view of a region I_{c} of the semiconductor memory device according to this embodiment illustrated in FIG. 1. Hereinafter, the same configuration of views A, B and C is true of FIGS. 5A to 11C.

As illustrated in FIGS. 4A and 4B, the first insulating film 4a is first formed on the semiconductor substrate 1 in which the element isolation regions 2 have been previously formed, by a chemical vapor deposition (CVD) method, for example. The first insulating film 4a is, for example, a silicon oxide film. A pattern is formed in the first insulating film 4a using a photolithographic patterning and etching method so that individual first contacts 3 will be located on the active regions AA in the substrate 1 (not illustrated). To obtain the structure shown in FIGS. 4A and 4B, after having had a mask formed thereon by photolithographic techniques (applying, pattern exposing, and developing a resist to form a pattern of openings over the continuous first insulating film 4a) the first insulating film 4a is etched using a reactive ion etching (RIE) method based on the pattern to form the individual contact holes 5a as seen in FIGS. 4A and 4B.

As illustrated in FIGS. 5A and 5B, the contact holes 5a are filled with a conductive material by, for example, a physical vapor deposition (PVD) or CVD method to thereby form the first contacts 3. Any surplus of the conductive material filling the contact holes 5a and overlying the surface of the first insulating film 4a is removed using a chemical mechanical polishing (CMP) method. Thereafter, the second insulating film 4b is formed on the first insulating film 4a and the first contact 3 by, for example, a chemical vapor deposition (CVD) method. The second insulating film 4b is, for example, a silicon oxide film. A photoresist is applied onto the second insulating film 4b and patterned in a photolithography step to form a resist pattern 9 having an opening pattern. The portion of the second insulating film 4b underlying the resist pattern openings is removed by reactive ion etching (RIE) to form a trench 5b that extends in the second insulating film 4b to, and expose a top surface of, the first contacts 3, and extends in the X direction so as to expose a plurality of first contacts 3 at the base thereof. As illustrated in FIG. 5B, the trench 5b has a shape in which the width of the upper portion thereof in the Y direction is wider than the width of the lower portion thereof in the Y direction. The shape leads to an effect of promoting the filling of a conductive material therein.

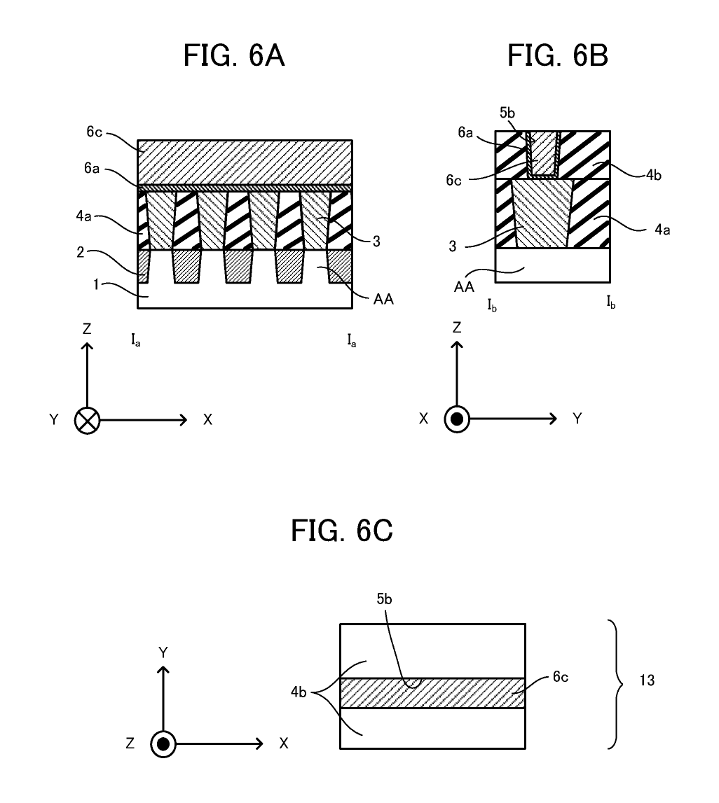

As illustrated in FIGS. 6A and 6B, the barrier metal layer 6a is formed on the side walls and the bottom surface of the trench 5b. The barrier metal layer 6a is formed of, for example, titanium nitride (TiN). The titanium nitride (TiN) is formed by, for example, a physical vapor deposition (PVD) or CVD method. A first conductive film 6c is formed in the trench 5b over the barrier metal layer 6a. The first conductive film 6c is formed of a conductive material such as, for example, tungsten by, for example, a PVD method or a CVD method. Thereafter, any surplus barrier metal layer 6a and first conductive film 6c extending above the trench 5b is removed using chemical mechanical polishing (CMP) to planarize the surface of the second insulating film 4b and the exposed first conductive film 6c and barrier metal layer 6a.

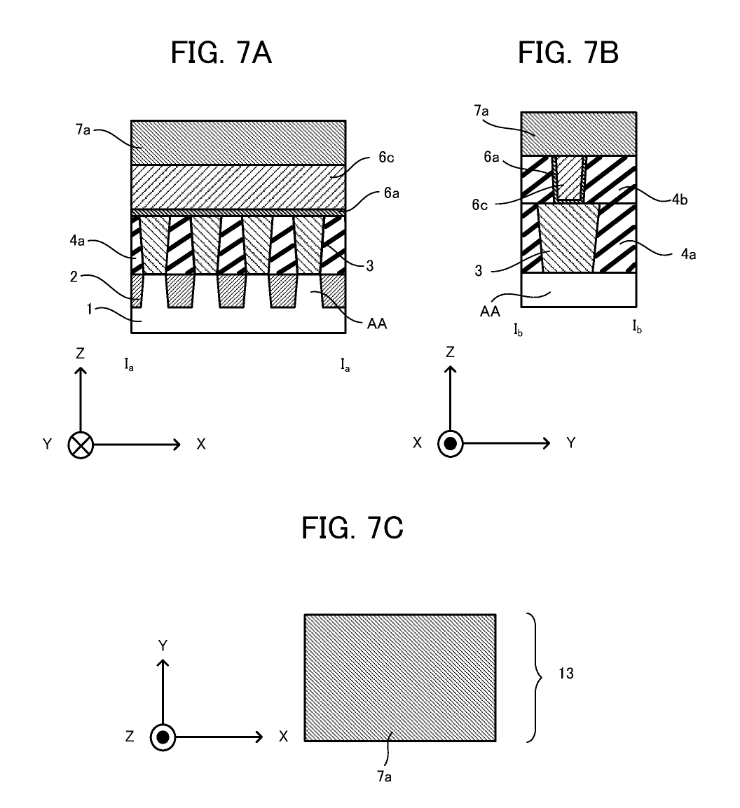

As illustrated in FIGS. 7A and 7B, a second conductive film 7a is formed on the first conductive film 6c and the second insulating film 4b by, for example, a PVD method or a CVD method. The second conductive film 7a is a conductive material such as, for example, tungsten, and preferably has an etching rate which is the same as or equivalent to that of the first conductive film 6c.

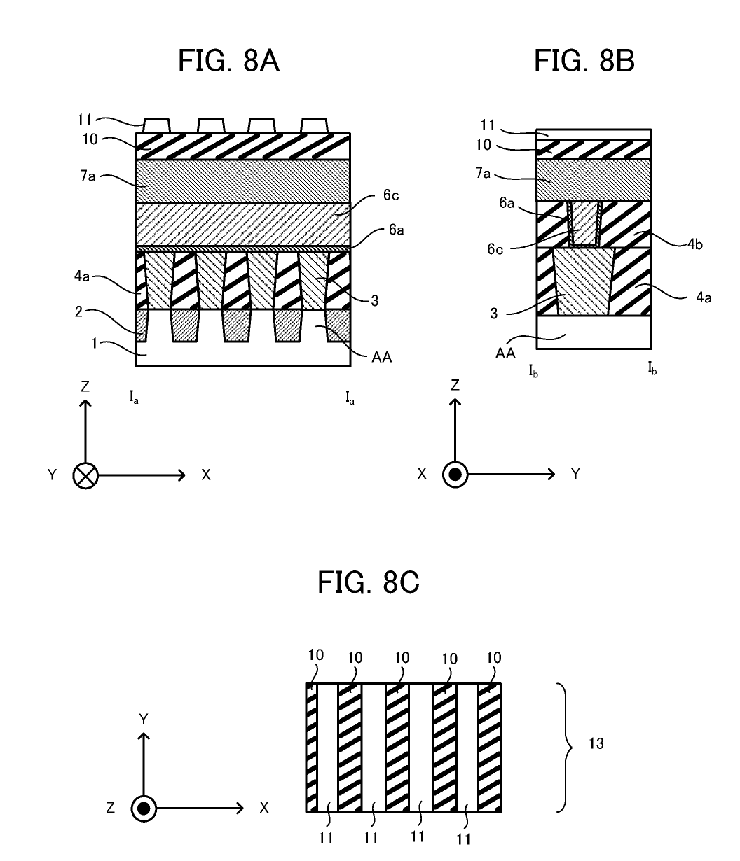

As illustrated in FIGS. 8A and 8B, a hard mask layer 10 is formed on the second conductive film 7a. The hard mask layer 10 is formed of, for example, a silicon oxide film, and has an etching rate characteristic which is the same as or equivalent to those of the first insulating film 4a and the second insulating film 4b. In addition, the hard mask is a film having a high etching selection ratio, i.e., a much lower etch rate in an etch environment for etching the conductive films 6c, 7a, as compared to the first conductive film 6c, the second conductive film 7a, and the barrier metal layer 6a. The hard mask 10 is formed by, for example, a CVD method. Thereafter, a photoresist is applied onto the hard mask layer 10 to form a wiring pattern mask 11 having a series of spaced stripes of photoresist that extend in the Y direction having gaps therebetween which are spaced apart in the X direction, using a lithography technique or the like.

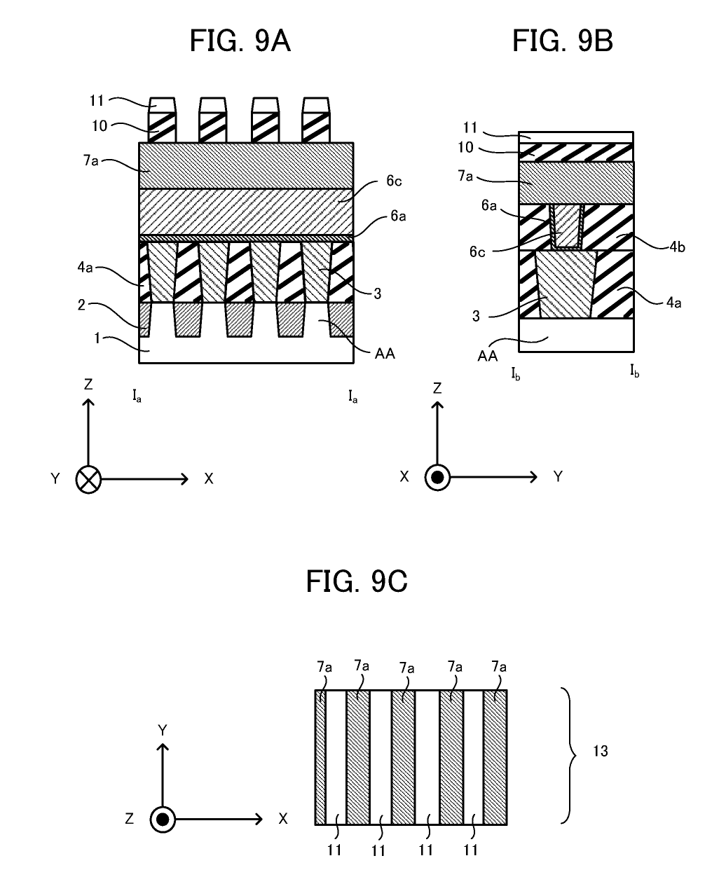

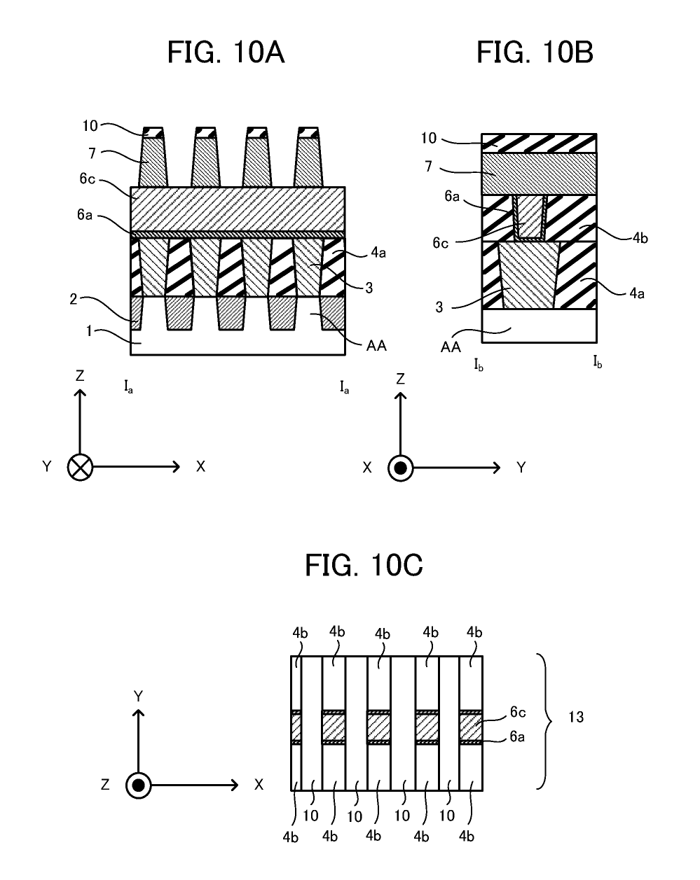

As illustrated in FIGS. 9A to 9C, the hard mask 10 material is processed into the shape of the wiring pattern mask 11 based on the opening pattern of the wiring pattern mask 11. Thus, the hard mask 10 is processed into the shape of the wiring pattern mask 11 having stripes, spaced apart in the X direction, and extending parallel to one another in the Y direction. The second conductive film 7a is processed by, for example, RIE and etching the conductive film 7a using the opening pattern in the wiring pattern mask 11 and the hard mask layer 10. In this case, since an etching rate of the hard mask layer 10 is significantly lower than an etching rate of the second conductive film 7a, the second conductive film 7a is etched into a wiring line shape in a locations where the stripes of the hard mask 10 material is, and remains, present. Thus, as illustrated in FIGS. 10A and 10B, the second conductive film 7a is processed into metal wiring lines 7 formed in the shape of the wiring pattern mask 11, such that the individual wiring lines 7 are formed spaced from one another in the X direction to extend over multiple contacts 6 over their length in the Y direction.

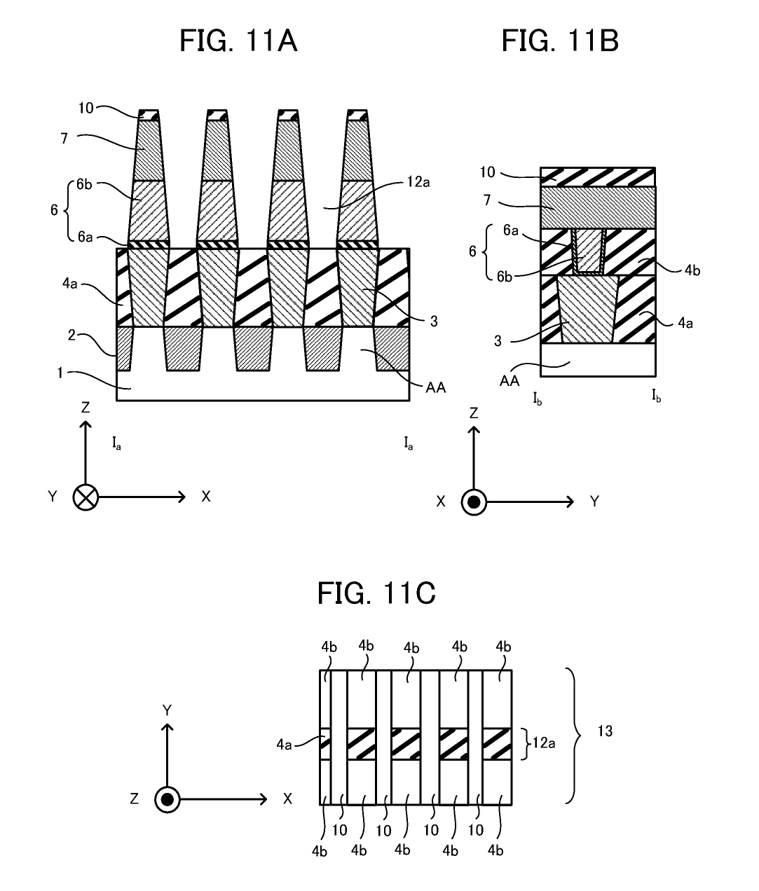

As illustrated in FIGS. 10A and 10B, after the individual metal wiring lines 7 are patterned from the second conductive film 7a, the first conductive film 6c and the barrier metal layer 6a, which extend in a direction orthogonal to the extending direction of the second insulating film 4b and the metal wiring lines 7, are exposed at, i.e., where they extend across, locations where the second conductive film 7a has been completely removed. By continuing an etch process, the first conductive film 6c and the barrier metal layer 6a are removed in the exposed locations between the wiring lines 7 by, for example, RIE such that individual contacts 6 are formed having the sidewall thereof, as viewed in the Y direction as shown in FIG. 11A, extending as a continuous extension of the sidewall of the metal wiring line 7 extending thereover, and as viewed in the Y-direction, as shown in FIG. 11B, the side walls of the material of the first conductive film 6c remaining to form the contact 6 are covered by the barrier film 6a. This is possible because the first conductive film 6c and the barrier metal layer 6a have an etching rate which is substantially equivalent to that of the second conductive film 7a, and the second insulating film 4b has an etching rate which is equivalent to that of the hard mask 10, and thus an etch rate significantly less than that of the first conductive film 6c and the barrier metal layer 6a and second conductive film 7a. Accordingly, among the first conductive film 6c, the second insulating film 4b and the metal wiring lines 7 which are exposed, only the first conductive film 6c and the barrier metal layer 6a are etched and removed, and the second insulating film 4b remains without being etched. Thus, as illustrated in FIGS. 11A to 11C, the metal wiring lines 7 and the individual second contacts 6 aligned with, and overlying, the first contacts 3 are formed.

As illustrated in FIG. 11A, in an interface or contacting surface between the metal wiring lines 7 and the second contacts 6, the lateral sides of the metal wiring lines 7 and the second contacts 6 are flush with each other when viewed from the cross-section in the X direction. In addition, the metal wiring lines 7 and the second contacts 6 are formed in such a manner that the widths thereof in the X direction continuously become wider from the uppermost portion of the metal wiring lines 7 to the lowermost portion of the second contacts 6. In addition, a space region 12a is formed between the adjacent second contacts 6. In addition, as illustrated in FIG. 11B, each second contact 6 is formed in such a manner that the width thereof in the Y direction continuously becomes narrower from the uppermost portion of the second contact 6 toward the lowermost portion of the second contact 6.

Thereafter, as illustrated in FIGS. 2 and 3, the third insulating film 4c is formed on the metal wiring lines 7, between the adjacent metal wirings lines 7, and between the adjacent second contacts 6. The third insulating film 4c is a silicon oxide film formed by, for example, a CVD method. The space region 12a is formed between the adjacent metal wiring lines 7 and between the adjacent second contacts 6. Where the third insulating film 4c has not filled the space region 12a between adjacent wiring lines 7 and contacts 6, cavity is formed which is the insulating region 8. The insulating region 8 is an air gap containing, for example, air or the gaseous environment in which the third insulating film 4c was formed. A dielectric constant of the air gap is lower than that of the second insulating film 4b.

As described above, in the semiconductor memory device 100 created by this manufacturing method, the widths of the metal wiring lines 7 and the second contacts 6 in the X direction become wider from the uppermost portion of the metal wiring lines 7 to the lowermost portion of the second contacts 6, and the lateral sides of the metal wiring lines 7 and the second contacts 6 are flush with each other when viewed from the Y direction as shown in FIG. 2.

Based on this structure, and by forming the metal wiring lines 7 and separating the contacts from a bulk metal layer 6c using a single mask, misalignment between the lowermost contact 6 contacting surface of each metal line and the underlying uppermost wiring line 7 contacting surface of the contacts 6 does not occur, i.e., they are self aligned. Thus, it is possible to suppress leakage current between the adjacent wirings. In addition, a contact area between the metal wiring 7 and the second contact 6 is increased to be as large as the upper surface of the contacts 6, because no misalignment between the wiring lines 7 and the underlying contacts 6 can occur. Thus, it is possible to reduce contact resistance. Further, in the contact line bit region 13 as illustrated in FIG. 1, the adjacent second contacts 6 are repeatedly positioned in a row in the X direction without being shifted in the Y direction along the length of the row which would result in a staggered or offset row shape. For this reason, it is possible to reduce the width of the contact line bit region 13 in the Y direction. Thus, it is possible to reduce a chip (memory) area. In addition, since an air gap is present between the metal wiring 7 and the second contact 6, it is possible reduce parasitic capacitance.

Although the structure and manufacturing method of the second contact 6 and the metal wiring 7 in the contact line bit region 13 are described in this embodiment, it is also possible to form a contact and a metal wiring in a peripheral circuit (not illustrated) by using the same manufacturing method. Thus, also in the peripheral circuit, it is possible to reduce a value of contact resistance between the metal wiring and the contact and to reduce parasitic capacitance.

### Second Embodiment

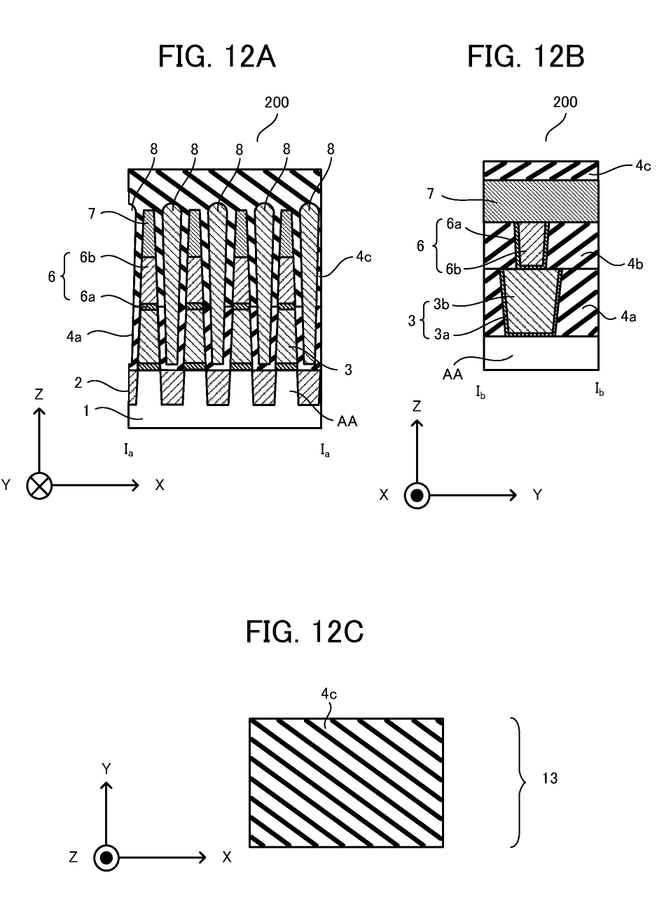

A semiconductor memory device 200 according to a second embodiment will be described below with reference to FIGS. 12A to 12C. FIG. 12A is a cross-sectional view taken along line Iₐ-Iₐ of the semiconductor memory device according to this embodiment illustrated in FIG. 1, and FIG. 12B is a cross-sectional view taken along line I_{b}-I_{b} of the semiconductor memory device according to this embodiment illustrated in FIG. 1. FIG. 12C is an enlarged plan view of the region I_{c} of the semiconductor memory device according to this embodiment illustrated in FIG. 1.

The second embodiment is different from the first embodiment in that a first contact 3 is formed at the same time that the metal wiring lines 7 and second contacts 6 are formed.

Since the second embodiment is the same as the first embodiment except that the final outline of the first contacts 3 is formed at the same time that the metal wiring lines 7 and the final outline of the second contacts 6 are formed, the same components are denoted by the same reference numerals, and the detailed description thereof will be omitted.

A configuration of the semiconductor memory device 200 according to the second embodiment will be described.

As illustrated in FIG. 12A, the first contacts 3 are provided on respective active regions AA in a row in the X direction in a contact line bit region 13 between adjacent selector gate lines SG. The first contacts 3 are disposed in a row extending in the X direction so as to be adjacent to, but spaced from, one another. The width of the upper portion of the first contact 3 in the X direction is narrower than the width of the lower portion of the first contact 3 in the X direction.

The second contacts 6 are provided on the first contacts 3. The width of the lower portion of the second contacts 6 in the X direction is the same as the width of the upper surface area of contact 3, i.e., the surface thereof over which a barrier layer 6a is formed. The width of the upper portion of the second contacts 6 in the X direction is narrower than the width of the lower portion of the second contacts 6 in the X direction.

The metal wiring lines 7 extend over, and contact the uppermost surfaces of, the second contacts 6, each metal wiring line 7 contacting a different plurality of second contacts 6. The width of the lower portion of the metal wiring lines 7 in the X direction is the same as the width of a upper portion of the second contacts 6 at which the underside of the wiring lines 7 contact the upper surface of the contacts 6. The width of the upper portion of the metal wiring 7 lines in the X direction is narrower than that of the lower portion of the metal wiring lines 7 in the X direction. In other words, the configuration is made such that the width in the X direction continuously becomes wider from the uppermost portion of the metal wiring 7 to the lowermost portion of the first contact 3. In addition, the lateral sides of the metal wiring lines 7, underlying contacts 6 and the yet further underlying first contacts 3 are flush with each other at the junctions therebetween when viewed from the Y direction as is shown in FIG. 12A. As illustrated in FIG. 12B, the metal wiring lines 7 extend in the Y direction.

A third insulating film 4c is provided on the metal wiring lines 7, between the adjacent metal wiring lines 7, between the adjacent second contacts 6, and between the adjacent first contacts 3. By the formation of the third insulating film 4c, an insulating region 8 having a dielectric constant lower than that of the insulating film 4 is present between the adjacent metal wiring lines 7, between the adjacent second contacts 6, and between the adjacent first contacts 3.

As described above, since the lateral sides of the metal wiring lines 7, underlying contacts 6 and further underlying first contacts 3 are flush with each other when viewed from the Y direction as shown in FIG. 12A, each contact area, from the contact area of the metal wiring lines 7 to the upper surface of the contacts which the wiring line 7 overlies, and the contact area between the underside of each contact and the upper surface of each first contact 3, having the barrier film 6a therebetween, is the maximum possible, because no misalignments are present. Thus, it is possible to reduce contact resistance in the first contact 3, second contact 6 and wiring line 7 stack. In addition, misalignment does not occur between the metal wiring lines 7 and the underlying second contact 6s. As a result, a minimum distance is maintained from a region between the adjacent metal wiring lines 7 to a region between the adjacent first contacts 3, and thus it is possible to suppress an increase in leakage current across that distance. In addition, the insulating region 8 having a low dielectric constant is present between the adjacent metal wiring lines 7, between the adjacent second contacts 6, and between the adjacent first contacts 3 by virtue of the presence of the insulating film 4 therebetween, and thus it is possible to reduce parasitic capacitance.

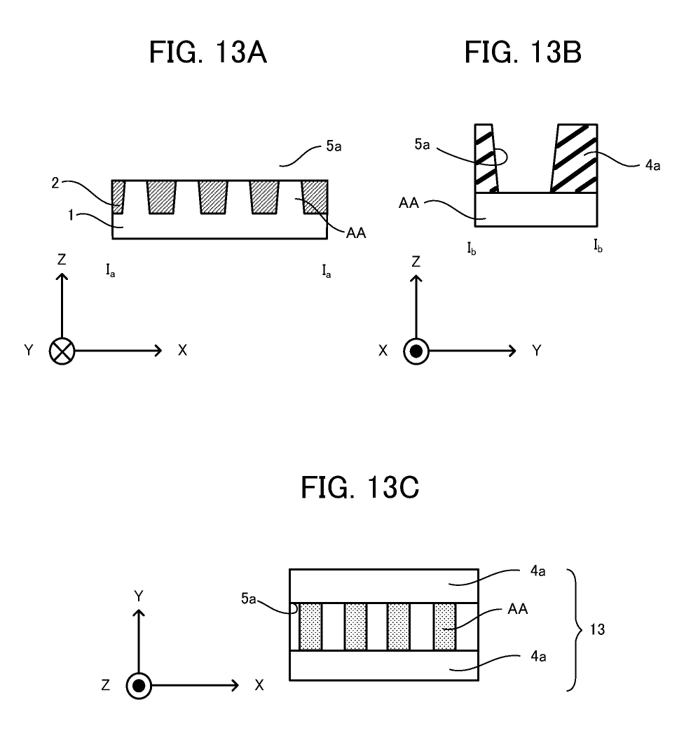

Next, a method of manufacturing the semiconductor memory device according to this embodiment will be described with reference to FIGS. 13A to 17C. FIG. 13A is a cross-sectional view taken along line Iₐ-Iₐ of the semiconductor memory device according to this embodiment illustrated in FIG. 1, and FIG. 13B is a cross-sectional view taken along line I_{b}-I_{b} of the semiconductor memory device according to this embodiment illustrated in FIG. 1. FIG. 13C is an enlarged plan view of the region I_{c} of the semiconductor memory device illustrated in FIG. 1.

As illustrated in FIGS. 13A and 13B, a patterned first insulating film 4a is shown. To obtain the patterned film, a first insulating film 4a is formed on the semiconductor substrate 1, in which the regions AA extending in the Y direction and spaced apart in the X direction were previously formed, by a chemical vapor deposition (CVD) method, for example. A photoresist is applied onto the deposited first insulating film 4a to form a resist pattern (not illustrated) having trench shaped openings extending in the X direction, and spaced apart in the Y direction, by a lithography technique. Thereafter, a trench 5a extending in the X direction is formed in the first insulating film 4a by, for example, reactive ion etching (RIE) using the resist pattern to expose a top surface of the semiconductor substrate at the base of a plurality of parallel trenches 5a.

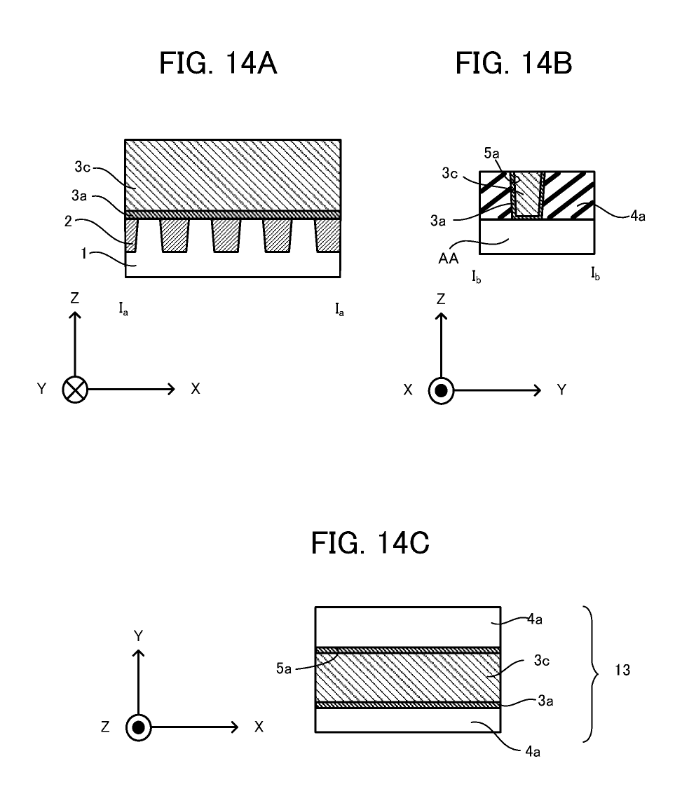

A barrier metal layer 3a is formed on the side wall and the bottom surface of the trench 5a. The barrier metal layer 3a is formed of, for example, titanium nitride (TiN). The titanium nitride (TiN) is formed by, for example, a CVD method. As illustrated in FIGS. 14A and 14B, a third conductive film 3c is provided in the trench 5a through the barrier metal layer 3a by, for example, a sputtering method or a CVD method. The third conductive film 3c is a conductive material such as, for example, tungsten, and has an etching rate which is the same as or equivalent to those of a first conductive film 6c and a second conductive film 7a. The third conductive film 3c filling the trench will ultimately be etched into individual first contacts 3 as described later herein. Thereafter, any third conductive film 3c formed on the first insulating film 4a outside or above the trench 5a is removed using chemical mechanical polish (CMP) to thereby planarize a surface.

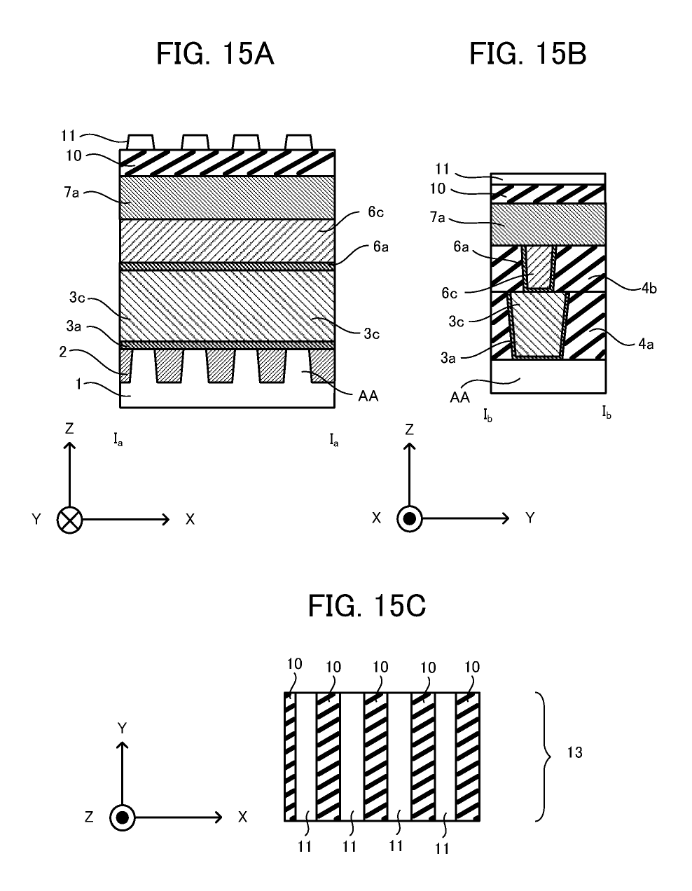

Thereafter, as illustrated in FIGS. 15A to 15C, the processes for forming the first conductive film 6c, the second conductive film 7a, a hard mask 10, and a wiring pattern mask 11 are the same as those in the first embodiment. Meanwhile, the second embodiment is the same as the first embodiment in that the hard mask 10 has an etching rate characteristic which is the same as or similar to those of the first insulating film 4a and a second insulating film 4b and in that the hard mask has a high etching selection ratio to the first conductive film 6c, the second conductive film 7a, and in this embodiment, to the third conductive film 3c.

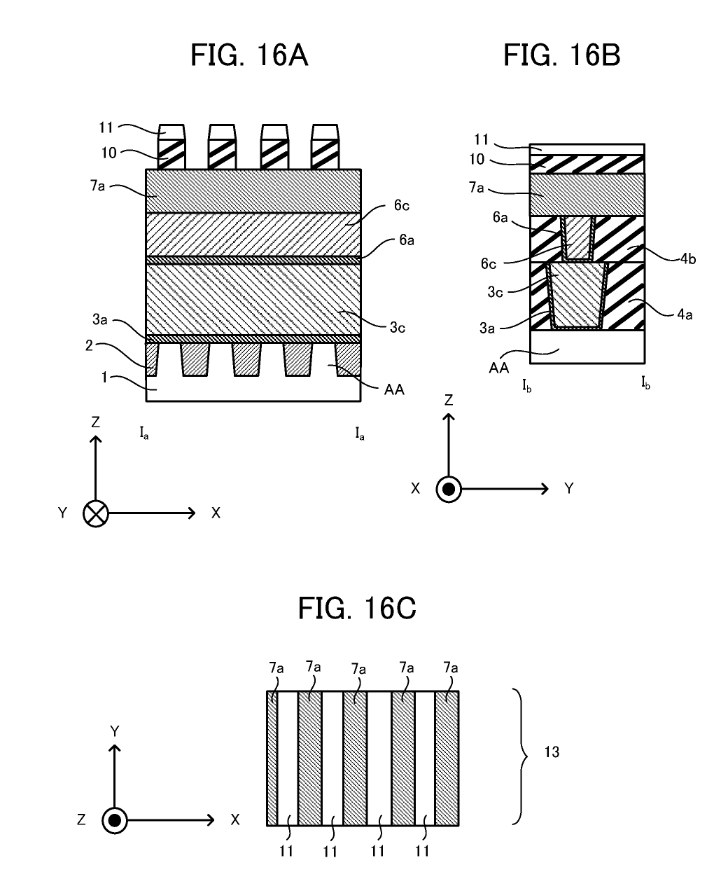

As illustrated in FIGS. 16A and 16B, the hard mask 10 is processed into the shape of the wiring pattern mask 11 based on the opening pattern in the wiring pattern mask 11. Thus, the hard mask 10 is processed into the shape of the wiring pattern mask 11 extending in the Y direction.

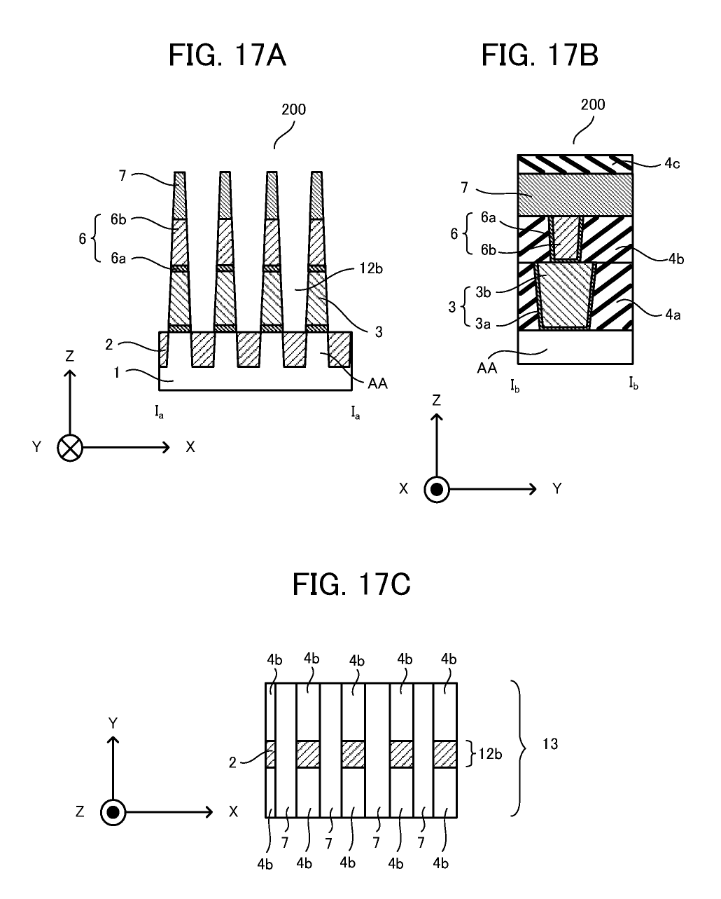

Next, as illustrated in FIGS. 17A to 17C, for example, RIE is performed on the second conductive film 7a based on the wiring pattern mask 11 and the hard mask 10. The second conductive film 7a is etched into a wiring line shape in locations where the hard mask 10 remains, and thus the metal wiring lines 7 are formed. Further, etching, for example RIE, is performed on the first conductive film 6c, which is selectively exposed by the removal of the second conductive film 7a and then the barrier metal layer 6a, and the third conductive film 3c are etched using the pattern of the wiring pattern mask 11 and the hard mask 10 (and the overlying wiring layer 7 in the case of second contact 6, and the second contact 6 in the case of first contact 3). The first conductive film 6c remaining after the RIE step forms individual second contacts 6, and the third conductive film 3c remaining after the RIE step form the individual first contacts 3.

As described above, the first conductive film 6c, the second conductive film 7a, and the third conductive film 3c can be processed into the second contacts 6, the metal wiring lines 7, and the first contacts 3, respectively, by, for example, RIE based on the wiring pattern mask 11 and the hard mask 10. In addition, a space region 12b is formed between the second contact 6 and the first contact 3. The stack of wiring lines 7 located over second contacts 6, in turn located over first contacts 3, is tapered from the uppermost portion of the wiring lines to the lowermost portion of the first contact because the sides of the hardmask and wiring layer mask are slowly eroded (etched) away as the etching of the multi layer stack progresses, leading to the tapering effect.

As illustrated in FIGS. 12A to 12C, the third insulating film 4c is formed on the metal wiring lines 7, between the adjacent metal wiring lines 7, between the adjacent second contacts 6, and between the adjacent first contacts 3. The third insulating film 4c is a silicon oxide film which is formed by, for example, a CVD method. A cavity is formed in regions between the metal wiring lines 7, between the second contacts 6, and between the first contacts 3, in regions where the third insulating film 4c does not sufficiently fill the gap between the adjacent metal wiring lines 7, second contacts 6, and first contacts 3. This cavity forms the insulating region 8. The insulating region 8 is an air gap such as, for example, air or the gas environment in which the third insulating film was formed. A dielectric constant of the air gap is lower than that of the second insulating film 4b.

According to this manufacturing method, the widths of the metal wiring lines 7, the second contacts 6, and the first contacts 3 in the X direction continuously become wider from the uppermost end of the metal wiring lines 7 to the lowermost end of the first contact 3 closest to the substrate 1, and the lateral sides of the metal wiring lines 7, the second contacts 6, and the first contacts 3 are flush with each other when viewed from the Y direction as is shown in FIG. 17A. As a result, in the semiconductor device 200 manufactured by the manufacturing method according to this embodiment, misalignment does not occur in an interface surface between the metal wiring 7 and the second contact 6 and an interface surface between the second contact 6 and the first contact 3. Thus, it is possible to suppress an increase in leakage current between the adjacent wiring lines. In addition, an interface or contact area between the metal wiring 7 and the second contact 6 and an interface or contact area between the second contact 6 and the first contact 3 increases to a maximal possible amount because there is no misalignment at these interfaces. As a result, it is possible to reduce contact resistance. Further, in the contact line bit region 13 as illustrated in FIG. 1, the adjacent second contacts 6 can be formed to be positioned in a row in the X direction without being shifted in the Y direction. Accordingly, since the tolerance on the length of the contact line bit region 13 in the Y direction is reduced, it is possible to reduce the length. As a result, it is possible to reduce a chip area. In addition, since an air gap is present between the metal wiring 7 and the second contact 6, it is possible reduce parasitic capacitance.

Although the structure and manufacturing method of the first contact 3, the second contact 6, and the metal wiring lines 7 in the contact line bit region 13 are described in this embodiment, it is also possible to form a contact and a metal wiring in a peripheral circuit (not illustrated) by using the same manufacturing method. Thus, also in the peripheral circuit, it is possible to reduce a value of contact resistance between the metal wiring and the contact and to suppress an increase in parasitic capacitance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor substrate including an active region and an element isolation region which are alternately arranged in a first direction and extend in a second direction orthogonal to the first direction;
a first contact portion that is electrically connected to the semiconductor substrate, and has a width in the first direction which continuously becomes narrower over the extent thereof in a third direction perpendicular to the semiconductor substrate, and a width in the second direction which continuously becomes wider over the extent thereof in the third direction; and
a metal wiring line over an upper portion of the first contact portion so as to extend in the second direction, having a width in the first direction at the lowermost surface thereof contacting the first contact portion which is as large as a width of the first contact portion and which continuously becomes narrower over the extent thereof in the third direction.

2. The device according to claim 1, wherein lateral sides of the first contact portion and the metal wiring line when viewed from the first direction are flush with each other.

3. The device according to claim 1, further comprising:
a second contact portion that is provided on a lower portion of the first contact portion and is electrically connected to the semiconductor substrate.

4. The device according to claim 3, wherein
the width of an upper portion of the second contact portion connected to the first contact portion in the first direction is as large as a width of a lower portion of the first contact portion facing the second contact portion,
the width of the second contact portion in the first direction continuously becomes narrower over the extent thereof in the third direction, and
the width of the second contact portion in the second direction continuously becomes wider over the extent thereof in the third direction.

5. The device according to claim 4, wherein
lateral sides of the second contact portion, the first contact portion, and the metal wiring line, when viewed from the first direction, are flush with each other.

6. The device according to claim 4, wherein
a plurality of the metal wiring lines, a plurality of the first contact portions, and a plurality of the second contact portions are provided in the first direction,
an insulating film is provided between the adjacent metal wiring lines, between the adjacent first contact portions, and between the adjacent second contact portions, and
an insulating region is provided between the adjacent metal wiring lines, between the adjacent first contact portions, and between the adjacent second contact portions within the insulating film.

7. The device according to claim 6, wherein
the insulating region is an air gap.

8. The device according to claim 3, wherein lateral sides of the first contact portion and the metal wiring line, when viewed from the first direction, are flush with each other, and the lateral sides of the first contact portion and second contact portion form an obtuse angle with each other.

9. The device according to claim 3, further comprising
a barrier layer interposed between the first contact portion and the second contact portion, and
the contact areas between the first contact portion and the barrier layer, and between the second contact portion and the barrier layer, is larger than the contact area between the wiring layer and the first contact portion.

10. The device according to claim 1, wherein
a plurality of the metal wiring lines and a plurality of the first contact portions are provided in the first direction,
an insulating film is provided between the adjacent metal wiring lines and between the adjacent first contact portions, and
an insulating region is provided between the adjacent metal wiring lines and between the adjacent first contact portions within the insulating film.

11. A method of manufacturing a semiconductor memory device, the method comprising:
forming a first contact portion on an active region in a semiconductor substrate;
forming a first insulating film on the first contact portion;
forming a first mask having a trench pattern on the first insulating film;
forming a first trench extending in the first direction by etching until a top surface of the first contact portion is exposed, using the first mask;
forming a first conductive film within the first trench;
forming a second conductive film on the first conductive film;
forming a second mask that extends in a second direction orthogonal to the first direction, on the second conductive film;
forming a metal wiring line by etching the second conductive film using the second mask; and
forming the second contact portion by further etching the first conductive film using the second mask.

12. The method according to claim 11, further comprising:
providing a plurality of the metal wiring lines and a plurality of the second contact portions and forming a second insulating film between the adjacent metal wiring lines and between the adjacent second contact portions and forming an insulating region between the adjacent metal wiring lines and between the adjacent second contact portions.

13. The method according to claim 11, further comprising:
forming the first contact portion as a first conductive film extending in the first direction.

14. The method according to claim 13, wherein the width of each of the conductive wiring layer, the second contact and the first contact decreases in a second direction orthogonal to the first direction over the extent thereof in a direction away from and orthogonal to the substrate.

15. The method according to claim 14, wherein a barrier layer is disposed between the first contact portion and the second contact portion.

16. A method of forming a self-aligned connection between a conductive wiring line and an active region of a memory cell array, comprising:
providing a substrate having a plurality of individual active regions accessible at a surface thereof;
forming a first insulating layer on the substrate and pattern etching the first insulating layer to form one or more openings therethrough which expose one or more active regions;
filling the one or more openings with a first conductive material;
forming a second insulating layer over the first conductive material and the first insulating material;
pattern etching one or more parallel trenches into the second insulating film, the trenches extending in a first direction and a surface of the first conductive material being exposed in the one or more parallel trenches;
filling the one or more parallel trenches with a second conductive material;
forming a third conductive material over the second conductive material and second insulating film;
forming a patterned hardmask layer having a plurality of stripe shaped openings therethrough and extending in a direction orthogonal to the first direction over the third conductive material;
pattern etching at least two trenches into the third conductive material through the stripe shaped openings in the hard mask and thereby forming at least one wiring line extending over a plurality of the trenches having the second conductive material therein; and
using the hardmask, further etching the second conductive material to form a second contact in a self aligned location below the wiring line.

17. The method claim 16, further comprising;
forming the one or more openings in the first insulating film as one or more trenches extending in the first direction; and
using the hardmask, and after etching the second conductive material, etching the first conductive material to form a self-aligned first contact.

18. The method of claim 17, wherein the sidewalls of the wiring line and the second contact etched using the hardmask are flush with one another.

19. The method of claim 18, wherein the width of each of the wiring lines and the second contacts extending in the first direction decreases in the direction orthogonal to the substrate in a direction extending away from the substrate.

20. The method of claim 17, further comprising:
forming the one or more openings in the first insulating layer as individual openings located individually over the individual active regions.
